(19) United States
(12) Patent Application Publication
(10) Pub. No.: US 2007/0212879 A1
(43) Pub. Date: Sep. 13, 2007

(54) FORMATION OF LATTICE-TUNING SEMICONDUCTOR SUBSTRATES

(76) Inventors: Timothy John Grasby, Solihull (GB); Adam Daniel Capewell, Warwichshire (GB); Evan Hubert Parker, Warwickshire (GB)

Correspondence Address: MARK D. SARALINO (GENERAL);RENNER, OTTO, BOISSELLE & SKLAR, LLP, 1621 EUCLID AVENUE, NINETEENTH FLOOR, CLEVELAND, OH, 44115-2191, US

(21) Appl. No.: 11/575,520

(22) PCT Filed: Sep. 21, 2005
(86) PCT No.: PCT/EP05/54732

§ 371 Date: Mar. 19, 2007

(30) Foreign Application Priority Data
Sep. 22, 2004 (GB) 0421036.5

(51) Int. Cl. H01L 21/44

(52) U.S. Cl. 438/680

(57) ABSTRACT

A method of forming a lattice-tuning semiconductor substrate comprises the steps of defining striped regions (16) on the surface of a silicon substrate (10) at which dislocations can preferentially form, growing a first SiGe layer (18) on the strips such that first dislocations (20) extend preferentially across the first SiGe layer between the striped regions to relieve the strain in the first SiGe layer in directions transverse to the stripes (16), and growing a second SiGe layer on top of the first SiGe layer such that second dislocations (22) form preferentially within the second SiGe layer to relieve the strain in the second SiGe layer in directions transverse to the first dislocations (20). The dislocations so produced serve to relax the material in two mutually transverse directions whilst being spatially separated so that the two sets of dislocations cannot interact with one another. Thus the density of threading dislocations and the surface roughness is greatly reduced, thus enhancing the performance of the virtual substrate by decreasing the disruption of the atomic lattice that can lead to scattering of electrons in the active devices and degradation of the speed of movement of the electrons.

This invention relates to the production of lattice-tuning semiconductor substrates, and is more particularly, but not exclusively, concerned with the production of relaxed SiGe (silicon/germanium) “virtual substrates” suitable for the growth of strained silicon or SiGe active layers and unstrained III-V semiconductor active layers within which active semiconductor devices, such as MOSFETs, may be fabricated.

It is known to epitaxially grow a strained Si layer on a Si wafer with a relaxed SiGe buffer layer interposed therebetween, and to fabricate semiconductor devices, such as MOSFETs, within the strained Si layer in order to enhance the properties of the semiconductor devices. The buffer layer is provided in order to increase the lattice spacing relative to the lattice spacing of the underlying Si substrate, and is generally called a virtual substrate.

It is known to epitaxially grow an alloy of silicon and germanium (SiGe) on the silicon substrate to form the buffer layer. Since the lattice spacing of SiGe is greater than the normal lattice spacing of Si, the desired increase in lattice spacing is achieved by the provision of such a buffer layer if the buffer layer is allowed to relax.

The relaxation of the buffer layer inevitably involves the production of dislocations in the buffer layer to relieve the strain. These dislocations generally form a half loop from the underlying surface which expands to form a long dislocation at the strained interface. However the production of threading dislocations which extend through the depth of the buffer layer is detrimental to the quality of the substrate, in that such dislocations can produce an uneven surface and can cause scattering of electrons within the active semiconductor devices. Furthermore, since many dislocations are required to relieve the strain in a SiGe layer, such dislocations inevitably interact with one another causing pinning of threading dislocations. Additionally more dislocations are required for further relaxation, and this can result in a higher density of threading dislocations.

Known techniques for producing such a buffer layer, such as are disclosed in U.S. Pat. No. 5,442,205, U.S. Pat. No. 5,221,413, WO 98/00857 and JP 6-252046, involve linearly grading the Ge composition in the layer in order that the strained interfaces are distributed over the graded region. This means that the dislocations that form are also distributed over the graded region and are therefore less likely to interact. However such techniques suffer from the fact that the main sources of dislocations are multiplication mechanisms in which many dislocations are generated from the same source, and this causes the dislocations to be clustered in groups, generally on the same atomic glide planes. The strain fields from these groups of dislocations can cause the virtual substrate surface to have large undulations which is both detrimental to the quality of the virtual substrate and has the added effect of trapping threading dislocations.

WO 04023536 describes a technique in which the buffer layer is formed by the selective growth of a first SiGe layer between parallel strips of oxide on a silicon surface followed by the growth of a second SiGe layer on top of the first SiGe layer so as to overgrow the oxide strips such that a continuous SiGe layer is formed. The provision of such a two layer growth technique allows the strain within the SiGe layers to be relieved by two distinct sets of orthogonal dislocations within the growth plane which are generated at separate times during growth. During selective growth within the oxide strips, dislocations preferentially nucleate from the oxide side walls and glide across the narrow dimension of the oxide window. These dislocations relieve strain in directions perpendicular to the dislocations only, the direction parallel to the dislocations remaining full strained. Growth of a second layer over the oxide strips proceeds with the strain in one direction fully relieved, but unrelieved in the other direction. This remaining strain is eventually relieved by other dislocation mechanisms causing dislocations to form in directions perpendicular to the dislocations formed between the oxide strips. Since the two sets of dislocation networks are formed at different times during the growth of the SiGe layers, the dislocations are unable to interact with each other in such a way as to cause pinning of threading dislocations or produce an uneven surface. However this technique may produce an uneven surface due to the growth of the upper layer being seeded from a plurality of seeding windows between the oxide strips. This provides the need for a polishing step during the growth of the upper layer to substantially planarise the surface. This planarisation step requires the interruption of growth, the removal of the substrate from the growth chamber, a chemical mechanical polishing step, a cleaning step and then the loading of the substrate back into the growth chamber. Each of these steps is time consuming and therefore may add to the cost.

It is an object of the invention to provide a method of forming a lattice-tuning semiconductor substrate in which performance is enhanced by decreasing the density of threading dislocations as compared with known techniques.

According to the present invention there is provided a method of forming a lattice-tuning semiconductor substrate, comprising:

(a) defining parallel strips (16) of material at the surface of a silicon substrate (10);

(b) growing a SiGe layer (18) over the surface of the silicon substrate incorporating the strips (16) of material such that the layer (18) extends continuously over the substrate surface and such that first dislocations are generated in a first direction (20) within the layer (18) transverse to the direction in which the strips (16) extend; and

(c) further growing SiGe on the layer (18) such that second dislocations are generated in a second direction (22) transverse to the first direction (20).

It is believed that such a technique is capable of producing high quality SiGe virtual substrates with extremely low levels of threading dislocations, that is with levels from less than 10⁶ dislocations per cm to virtually no threading dislocations. This is as a result of the fact that dislocations are produced which serve to relax the SiGe material in two mutually transverse directions whilst being formed at different times during the growth so that the two sets of dislocations cannot interact with one another in such a manner as to produce threading dislocations extending through the depth of the SiGe material.

As a result a thinner virtual substrate can be produced for a given Ge composition with both the threading dislocation density and the surface undulations being very greatly reduced. This results in a virtual substrate which is superior and allows power to be more readily dissipated. The decrease in roughness of the surface of the virtual substrate renders further processing more straightforward in that polishing of the surface can be minimised or dispensed with altogether, and loss of definition due to unevenness of the surface is minimised. The quality of the virtual substrate produced may be such as to render it suitable for specialised applications, for example in microelectronics or in full CMOS integration systems.

In this invention the energy barrier for dislocation nucleation can be tailored such that dislocations can be generated in one direction only before dislocation sources in the other direction become active.

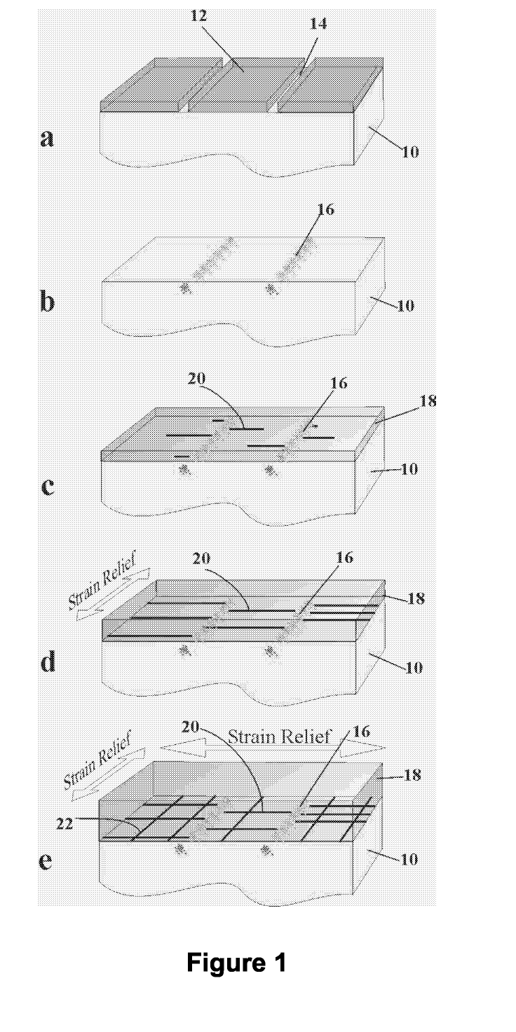

In a preferred embodiment illustrated in FIG. 1 subsurface damage is effected in parallel striped regions by ion implantation through a masking material with suitably etched regions. The damaged stripes allow the premature generation of misfit dislocations perpendicular to the striped regions. During this initial stage the SiGe layer will become relaxed in just one direction (perpendicular to the misfit dislocations). With continued growth the SiGe layer will relax in the other unrelieved direction due to dislocations nucleated randomly across the wafer. Since the dislocations that are generated randomly have a higher activation energy than those nucleated from the ion damaged regions, they will occur during a later stage of growth. Consequently, dislocation interactions will be reduced or eliminated and the threading dislocations should be able to glide unimpeded over the entire width of the wafer. The separation of the relaxation process into two distinct stages, with dislocations in the first stage perpendicular to dislocations in the second stage, enables the threading dislocation density and surface roughness associated with the dislocation interactions to be massively reduced. Additionally the thickness of these virtual substrates may be of the order of hundreds of nanometres (in comparison to several microns for conventional linearly graded virtual substrates), which has positive implications for thermal conductivity, process integration and cost.

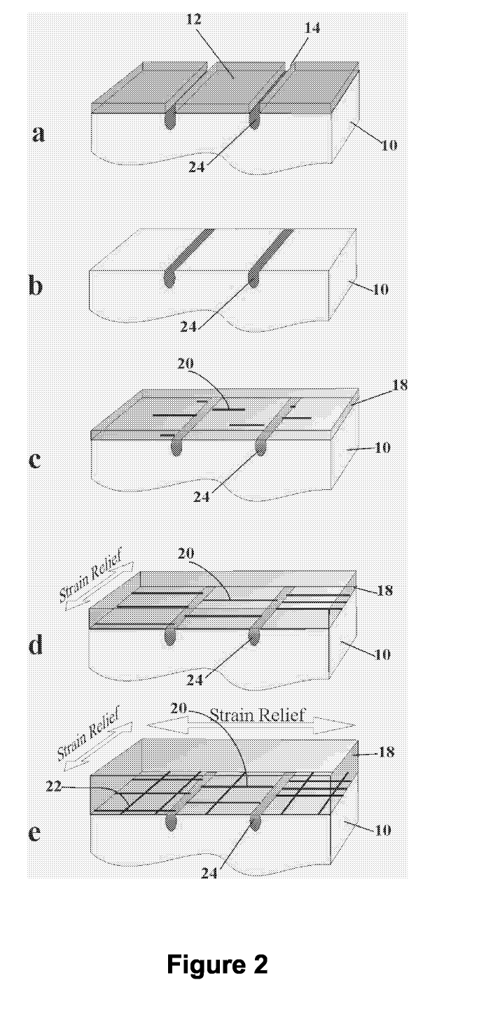

In a second embodiment illustrated in FIG. 2 the dislocations are also generated in two distinct stages, with dislocations generated in the first stage having a direction transverse to the dislocations generated in the second stage. However, in this embodiment, the premature generation of dislocations in one direction is effected by etching thin parallel troughs in the silicon substrate using a mask similar to the above preferred embodiment. An SiGe layer is then grown selectively in the trenches within the mask windows, using for example CVD with chlorinated chemistries, until the SiGe layer is level with the surface of the silicon substrate. The mask is then removed leaving the silicon substrate with long thin parallel stripes of SiGe level with the silicon surface. Non-selective growth of SiGe is then effected over the silicon substrate and SiGe stripes in order that dislocations nucleate preferentially from the initial SiGe stripes. The dislocations nucleate preferentially in these areas because the thickness of SiGe grown above the SiGe stripes is necessarily larger than the thickness above the silicon surface causing a greater level of strain above the stripes. The dislocations will therefore glide across the regions between the initial SiGe stripes causing relaxation in a direction parallel to the stripes. Further growth of SiGe will lead to nucleation of dislocations in a direction parallel to the stripes causing relaxation in the direction transverse to the relaxation caused by the initial dislocations. This will have the effect of reducing threading dislocations and surface roughness as in the preferred embodiment.

In order that the invention may be more fully understood, reference will now be made to the accompanying drawings, in which:

FIG. 1 shows successive steps in a method of forming a lattice-tuning semiconductor substrate in accordance with a preferred embodiment of the invention; and

FIG. 2 shows successive steps in a method of forming a lattice-tuning semiconductor substrate in accordance with a second embodiment of the invention.

The following description is directed to the formation of a lattice-tuning Si substrate on an underlying Si substrate with the interposition of a SiGe buffer layer. However it should be appreciated that the invention is also applicable to the production of other types of lattice-tuning semiconductor substrates, including substrates terminating at fully relaxed pure Ge allowing III-V incorporation with silicon. It is also possible in accordance with the invention to incorporate one or more surfactants, such as antimony for example, in the epitaxial growth process in order to produce even smoother virtual substrate surfaces and lower density threading dislocations by reducing surface energy.

Referring to FIG. 1a, in the preferred embodiment long parallel striped windows 14 are defined in an implantation mask 12 deposited onto a silicon substrate 10. The direction of the stripes is along one of the <110> directions that lie in the growth plane. The implantation mask is preferably oxide, although spin on resist or other implantation-hard materials can also be contemplated. The thickness of the implantation mask can vary from 1 to 10 000 nm, but a more typical range would be between 10 and 500 nm dependant on the implantation energy. The width of the windows defined in the implantation mask can be in the range 0.1 to 10 000 nm, and preferably in the range 10 and 2000 nm. The length of the striped windows can be in the range 10 μm to the full diameter of the silicon substrate. The spacing apart of the windows can be in the range from 100 nm to 100 μm, and preferably in the range from 1 μm to 20 μm.

The substrate is subject to ionbombardment in order that the regions of exposed silicon substrate 14 are implanted with ions causing subsurface damage 16 as shown in FIG. 1b. The implanted species is most likely ions of Si, Ge, C, He or H, but other species capable of producing damage can also be used. The depth of the subsurface damage can be in the range 0.1 to 100 nm, but the range 100 nm to 10 μm is also possible. The temperature of the substrate during ion implantation can be in the range 77K to 1200° C., and preferably room temperature. The implantation mask is then removed using either suitable solvents, etchants or a polishing stage.

FIG. 1c shows the subsequent growth of a SiGe layer 18 over the ion damaged silicon substrate in order that dislocations 20 preferentially generate from the damaged stripes 16 and glide in a direction transverse to the stripes. The SiGe layer is most likely to be of constant composition throughout the growth, but the use of a graded profile up to the final germanium concentration is also possible. The thickness of the SiGe layer can be in the range 10 nm to 10 μm, and preferably in the range 100 nm to 1000 nm. The most likely growth technique of the SiGe is chemical vapour deposition (CVD), but MBE or any other epitaxial growth technique may also be used. The germanium composition of the SiGe layer may be in the range 10% to 100% germanium and can be deposited in the temperature range room temperature to 1100° C., and preferably in the range 500° C. to 1000° C. It is possible that a high temperature anneal (substantially above the growth temperature) may be employed in order to trigger the relaxation process.

The continued growth of SiGe as in FIG. 1d enables the dislocations that have formed transverse to the damaged stripes to glide in order to relieve the strain in the direction perpendicular to their line direction. This will continue until the strain in this direction is substantially relieved.

Further growth of SiGe as in FIG. 1e causes dislocations 22 to form in the direction perpendicular to the dislocations nucleated from the stripes 16. Since the activation energy for generation of dislocations is higher away from the damaged stripes, these dislocations will form later in the growth process, ideally not until the strain is completely relieved in the orthogonal direction.

Since the two sets of orthogonal dislocations form at different stages during the growth process, interactions between the dislocations is minimised and possibly completely eliminated. This will result in a surface with substantially reduced threading dislocations and undulations.

In this manner a high quality virtual substrate is produced which may be used for the growth of strained Si or SiGe active layers and unstrained III-V semiconductor active layers within which active semiconductor devices may be fabricated.

In the second embodiment long stripes are defined in an etch mask as in the first embodiment, as shown in FIG. 2a. The wafer is subjected to an etch process in order that troughs 24 are etched in the regions defined by the striped windows. The depth of the etched troughs is preferably in the range 5 to 100 nm, but depths of up to 1 μm are also possible.

A SiGe layer is then selectively grown such that the SiGe only grows in the regions defined by the striped windows. The thickness of the selectively grown SiGe is such that it becomes level with the surface of the silicon substrate 10. This can be achieved using chlorinated precursors such as dichlorosilane, and HCl in a CVD growth system in order that growth on the oxide mask is prevented. However, other growth techniques which enable the selective growth of SiGe in the oxide stripes are also possible.

The etch mask is then removed revealing long parallel stripes of SiGe 24 embedded in the silicon substrate 10 as shown in FIG. 2b. The removal of the mask can be effected by the use of etchants or by a polishing process. It is possible to effect the selective growth of SiGe in the troughs 24 using a non-selective technique, such as MBE, if the removal of the etch mask is performed in such a way that any growth of SiGe on the mask is also removed. This might be possible by choosing the correct chemistry for etching, or by a short polishing step to remove the SiGe from the mask, without removing a significant portion of the silicon substrate.

SiGe is then non-selectively grown over the entire wafer so as to cover the substrate and the SiGe stripes as shown in FIG. 2c. The extra strain energy in the SiGe layer in the regions above the SiGe stripes leads to premature dislocation generation from these regions. Dislocations will then form in a direction perpendicular to these stripes in a manner analogous to the first embodiment.

Further growth of SiGe ensures that dislocations form to completely relieve the strain in the direction along the stripes, as shown in FIG. 2d, and then at a later stage in the growth further dislocations form in the transverse direction to relieve the remaining strain, as shown in FIG. 2e, in an analogous way to the first embodiment. Since the strain energy of the SiGe above the silicon substrate is less than the strain energy above the SiGe stripes, the dislocations not generated from the SiGe stripes will form later in the growth and ideally not until the strain in the transverse direction is completely relieved. This mechanism, in which the strain is relieved by a two stage process, reduces the threading dislocation density and the surface undulations as described in the first embodiment.

The Ge composition within the SiGe material may be substantially constant through the thickness of the layer, although it would also be possible for the Ge composition to be graded so that it increases from a first composition at a lower level in the layer to a second, higher composition at a higher level in the layer.

Various modifications of the above-described method are possible within the scope of the invention. For example, other methods of generating dislocations prematurely exist apart from the two embodiments described above and these are also within the scope of the invention. For example, the surface of the substrate could be treated using a masking material with defined stripes as in the previous embodiments followed by a quick etch such that the exposed silicon surface is slightly damaged. The damaged areas will act to preferentially generate dislocations in one direction. In another embodiment the surface of the substrate could be treated with a laser to modify the surface in specific areas. For example a laser could be scanned across the silicon substrate, or imaged through a suitable mask, to produce surface strips in which the silicon has been annealed, or recrystallised, or in which silicon has been removed from the surface. Other surface treatments that could be generated by a laser to produce strips include laser annealing of ion implantation damage, laser-induced oxidation of the silicon surface or other forms of laser damage. The areas treated with the laser will act to preferentially generate dislocations in one direction during SiGe growth over the laser-treated strips.

It should be appreciated that the use of surface strips of material that are substantially parallel to one another but have edges that are not straight or uniform are also included within the scope of the invention. For example, in one embodiment, zigzag strips are provided having corners that act as nucleation centres for preferential generation of dislocations propagating transverse to the strips.

Furthermore the SiGe may be epitaxially grown such that growth only occurs in selected areas of the wafer. Thus the fabrication technique may be used to produce a virtual substrate in only one or more selected areas of the chip (as may be required for system-on-a-chip integration) in which enhanced circuit functionality is required, for example.

Also, this method can be extended to other lattice mismatched semiconductor systems where dislocations can be preferentially nucleated from striped areas after suitable treatment. These systems include GaAs and InP which have a similar cubic crystallographic structure as SiGe but other material systems are also contemplated.

The method of the invention is capable of a wide range of applications, including the provision of a virtual substrate for the growth of strained or relaxed Si, Ge or SiGe layers for fabrication of devices such as bipolar junction transistors (BJT), field effect transistors (FET) and resonance tunnelling diodes (RTD), as well as III-V semiconductor layers for high speed digital interface to CMOS technologies and optoelectronic applications including light emitting diodes (LEDs) and semiconductor lasers.

1. A method of forming a lattice-tuning semiconductor substrate, comprising:
(a) defining parallel strips of material at the surface of a silicon substrate;
(b) growing a SiGe layer over the surface of the silicon substrate incorporating the surface strips of material such that, during initial growth of the layer on the substrate surface, the layer extends continuously over the substrate surface and is not interrupted where it overgrows the surface strips and first dislocations are generated in a first directions within the layer transverse to the direction in which the surface strips extend; and
(c) further growing SiGe on the layer such that second dislocations are generated in a second direction transverse to the first directions.

2. A method according to claim 1, wherein the SiGe layer has a Ge composition ratio that is substantially constant within the layer.

3. A method according to claim 1, wherein the SiGe layer has a Ge composition ratio that increases within the layer from a first level to a second level greater than the first level.

4. A method according to claim 1, wherein the SiGe layer is grown at a temperature in the range from room temperature to 1100° C., and preferably in the range from 500° C. to 1000° C.

5. A method according to claim 1, wherein the SiGe layer is annealed at an elevated temperature in order to trigger relaxation of the strain in the layer.

6. A method according to claim 1, wherein the growth of the SiGe layer and the further growth of SiGe on the layer form parts of a single continuous growth process.

7. A method according to claim 1, wherein the strips of material at the surface of the silicon substrate are defined by a mask.

8. A method according to claim 7, wherein the mask is made of oxide.

9. A method according to claim 1, wherein the strips of material at the surface of the silicon substrate are subjected to ion bombardment.

10. A method according to claim 1, wherein the strips of material at the surface of the silicon substrate are produced by surface treatment using a laser.

11. A method according to claim 1, wherein the strips of material at the surface of the silicon substrate are subjected to etching to produce troughs, and SiGe material is grown in the troughs.

12. A method according to claim 1, wherein the strips of material at the surface of the silicon substrate are subjected to annealing.

13. A method according to claim 1, wherein the strips of material at the surface of the silicon substrate are produced by surface etching.

14. A method according to claim 1, wherein the SiGe layer is grown by a selective epitaxial growth process, such as chemical vapour deposition (CVD).

15. A method according to claim 1, wherein the surface strips have a width in the range from 0.1 nm to 10,000 nm, and preferably in the range from 2 nm to 2,000 nm.

16. A method according to claim 1, wherein the surface strips are spaced apart by a distance in the range from 100 nm to 100 μm, and preferably in the range from 1 μm to 20 μm.

17. A method according claim 1, further comprising the step of growing on top of the SiGe layer a strained Si layer within which one or more semiconductor devices are formed.

18. A method according to claim 1, wherein a material having the same crystal structure as SiGe, such as GaAs or InP, is grown in place of SiGe.

19. A method according to claim 1, wherein the surface strips have a zigzag shape with corners that act as nucleation centres for preferential generation of dislocations in the first direction.

20. A lattice-tuning semiconductor substrate formed by a method according to claim 1.
